(19) United States
(12) Patent Application Publication
(10) Pub. No.: US 2026/0024574 A1
(43) Pub. Date: Jan. 22, 2026

(54) MEMORY DEVICE INCLUDING MEMORY CELLS STACKED IN THREE DIMENSIONS

(71) Applicant: SAMSUNG ELECTRONICS CO., LTD., Suwon-si (KR)

(72) Inventors: Kyu-Chang Kang, Suwon-si (KR); Younghun Seo, Suwon-si (KR); ChangSik Yoo, Suwon-si (KR); Sang-Yun Kim, Suwon-si (KR); Young Seok Park, Suwon-si (KR); Hyun-Chul Yoon, Suwon-si (KR)

(21) Appl. No.: 19/014,015

(22) Filed: Jan. 8, 2025

(30) Foreign Application Priority Data
Jul. 16, 2024 (KR) 10-2024-0093952

(51) Int. Cl. G11C 11/4091; G11C 5/06; G11C 11/408; G11C 11/4094; G11C 11/4097; H10B 12/00

(52) U.S. Cl. CPC G11C 11/4091; G11C 5/063; G11C 11/4087; G11C 11/4094; G11C 11/4097; H10B 12/50

(57) ABSTRACT

An example memory device includes a bitline sense amplifier, a global bitline connected with the bitline sense amplifier, intermediate bitlines respectively connected with bonding pads electrically connecting a peripheral circuit structure and a cell array structure, local bitlines connected with each of the intermediate bitlines, memory cells connected with each of the local bitlines, and a bitline selection circuit selectively connecting a portion of the intermediate bitlines with the global bitline based on an address received from a memory controller during a read or write operation.

### CROSS-REFERENCE TO RELATED APPLICATION

This application claims priority under 35 U.S.C. § 119 to Korean Patent Application No. 10-2024-0093952 filed on Jul. 16, 2024, in the Korean Intellectual Property Office, the disclosures of which are incorporated by reference herein in their entireties.

### BACKGROUND

A semiconductor memory may be mainly classified as a volatile memory or a non-volatile memory. Read and write speeds of the volatile memory (for example, a DRAM or an SRAM) are fast, but the data stored in the volatile memory disappear when a power is turned off. In contrast, the non-volatile memory may retain data even when the power is turned off. Therefore, the non-volatile memory may be used to store contents which must be preserved regardless of whether power is supplied or not.

A representative example of a volatile memory device is a DRAM. A memory cell of a volatile memory device may include a single N-type transistor, serving as a switch, and a single capacitor storing electric charges DATA. Binary information “1” or “0” may correspond to the presence or absence of the electric charges stored in the capacitor in the memory cell, for example, whether a terminal voltage of a cell capacitor is high or low. The memory cell may be connected to a wordline and a bitline. The bitline may be connected to a sense amplifier. The sense amplifier may sense data, stored in the memory cell, through the bitline based on a voltage applied to the wordline.

The volatile memory device may stack memory cells in three dimensions to support as much capacity as possible in the same area. In order to stack the memory cells in three dimensions, bitlines or wordlines may be formed vertically. However, due to the high density of the memory cells, spacing between the bitlines is narrowing and the number of bitlines handled by a single bitline sense amplifier is increasing.

### SUMMARY

Example implementations of the present disclosure provide a memory device reducing loads of a bitline sense amplifier during a read or write operation by selectively controlling the number of local bitlines connected to one global bitline.

In some implementations, a memory device including: a bitline sense amplifier; a global bitline connected to the bitline sense amplifier; intermediate bitlines respectively connected to bonding pads electrically connecting a peripheral circuit structure and a cell array structure; local bitlines connected to each of the intermediate bitlines; memory cells connected to each of the local bitlines; and a bitline selection circuit selectively connecting a portion of the intermediate bitlines to the global bitline based on an address received from a memory controller during a read or write operation.

In some implementations, a memory device including: a cell array structure; and a peripheral circuit structure configured to be bonded to the cell array structure through a bonding process. The cell array structure includes: a memory cell array including sub-cell arrays formed in a direction perpendicular to a substrate; local bitlines extending from each of the sub-cell arrays toward the peripheral circuit structure; intermediate bitlines in which the local bitlines are grouped and connected in a specified unit; and first selection transistors respectively connected to the local bitlines. The peripheral circuit structure includes: a bitline sense amplifier; a global bitline connected to the bitline sense amplifier and connected to the intermediate bitlines; and a bitline multiplexer selectively connecting a portion of the local bitlines to the global bitline by turning on a portion of the first selection transistors based on an address received from a memory controller during a read or write operation.

In some implementations, a memory device including: a memory cell array including sub-cell arrays formed in a vertical direction on a substrate; local bitlines connected to memory cells in each of the sub-cell arrays; intermediate bitlines in which the local bitlines are grouped and connected in a first specified unit; global bitlines in which the intermediate bitlines are grouped and connected in a second specified unit; wordlines connected to the memory cells and formed in a direction perpendicular to the local bitlines; bitline sense amplifiers respectively connected to the global bitlines; and a bitline selection circuit selectively connecting a portion of the intermediate bitlines to each of the global bitlines based on an address received from a memory controller during a read or write operation.

### BRIEF DESCRIPTION OF THE DRAWINGS

The above and other objects and features of the present disclosure will become apparent by describing in detail implementations thereof with reference to the accompanying drawings.

FIG. 1 is a block diagram illustrating an example of a memory system.

FIG. 2 is a block diagram illustrating an example of a memory device of FIG. 1.

FIG. 3 is a three-dimensional diagram illustrating an example of a cell array structure of FIG. 2.

FIG. 4 is a structural diagram illustrating an example of a first sub-cell array of FIG. 3.

FIG. 5 is a diagram illustrating an example of a bitline selection circuit of FIG. 2.

FIG. 6 is a diagram illustrating an example of a bitline selection circuit of FIG. 2.

FIG. 7 is a block diagram illustrating an example of a memory device of FIG. 1.

FIG. 8 is a diagram illustrating an example of a bitline selection circuit of FIG. 7.

FIG. 9 is a diagram illustrating an example of a bitline selection circuit of FIG. 7.

FIG. 10 is a diagram illustrating an example of a bitline selection circuit of FIG. 7.

FIG. 11 is a flowchart illustrating an example of a bitline selection operation of a memory device of FIG. 2 or FIG. 7.

FIG. 12 is a diagram illustrating an example of a memory device of FIG. 1.

### DETAILED DESCRIPTION

Below, example implementations of the present disclosure will be described in detail and clearly to such an extent which an ordinary one in the art easily implements the present disclosure.

Below, a DRAM will be used as an example for illustrating features and functions of the present disclosure. However, other features and performances may be easily understood from information disclosed herein by a person of ordinary skill in the art. The present disclosure may be implemented by other implementations or applied thereto. Further, the detailed description may be modified or changed according to viewpoints and applications without escaping from the scope, spirit, and other objects of the present disclosure.

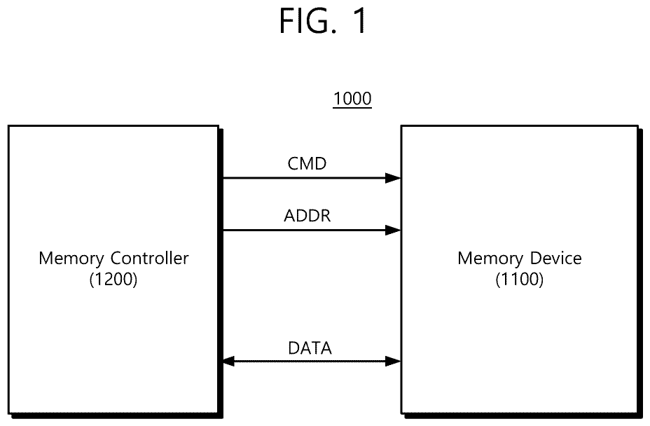

FIG. 1 is a block diagram illustrating an example of a memory system. Referring to FIG. 1, a memory system 1000 may include a memory device 1100 and a memory controller 1200.

The memory device 1100 may output data DATA, requested to be read by the memory controller 1200, to the memory controller 1200 or may store data DATA, requested to be written by the memory controller 1200, in a memory cell of the memory device 1100. The memory device 1100 may input and output data DATA based on the command CMD and the address ADDR. The memory device 1100 may include memory banks.

The memory device 1100 may be a volatile memory device such as a dynamic random access memory (DRAM), a synchronous dynamic random access memory (SDRAM), a double data rate (DDR) DRAM, a DDR SDRAM, a low-power double data rate (LPDDR) SDRAM, a graphics double data rate (GDDR) SDRAM, a Rambus dynamic random access memory (RDRAM), and a static random access memory (SRAM), or the like. Alternatively, the memory device 1100 may be implemented as a nonvolatile memory device such as a resistive RAM (RRAM), a phase change memory (PRAM), a magnetoresistive memory (MRAM), a ferroelectric memory (FRAM), a spin-transfer torque RAM (STT-RAM), or the like. In the present specification, the advantages of the present disclosure have been described with respect to a DRAM, but example implementations are not limited thereto.

The memory banks may include a memory cell array divided in units of banks, a row decoder, a column decoder, a sense amplifier, a write driver, or the like. The memory banks may store data DATA, requested to be written in the memory device 1100, through the write driver and may read data DATA, requested to be read, using the sense amplifier. The memory banks may further include a component for a refresh operation of storing and maintaining data in the cell array, or select circuits based on an address.

The memory controller 1200 may perform an access operation of writing data to the memory device 1100 or reading data stored in the memory device 1100. For example, the memory controller 1200 may generate a command CMD and an address ADDR for writing data to the memory device 1100 or reading data stored in the memory device 1100. The memory controller 1200 may include at least one of a control circuit controlling the memory device 1100, a system-on-chip (SoC) such as an application processor (AP), a central processing unit (CPU), a digital signal processor (DSP), and a graphics processing unit (GPU).

The memory controller 1200 may provide various signals to the memory device 1100 to control an overall operation of the memory device 1100. For example, the memory controller 1200 may control memory access operations of the memory device 1100 such as a read operation and a write operation. The memory controller 1200 may provide the command CMD and the address ADDR to the memory device 1100 to write data DATA in the memory device 1100 or to read data DATA from the memory device 1100.

The memory controller 1200 may generate various types of commands CMD to control the memory device 1100. For example, the memory controller 1200 may generate a bank request corresponding to a bank operation of changing a state of a memory bank, among memory banks, to read or write data DATA.

As an example, the bank request may include an active request for changing a state of a memory bank, among the memory banks, to an active state. The memory device 1100 may activate a row included in the memory bank, for example, a wordline, in response to the active request. The bank request may include a precharge request for changing the memory banks from an active state to a standby state after reading or writing of data DATA is completed.

In addition, the memory controller 1200 may generate an input/output (I/O) request (for example, a column address strobe (CAS) request) for the memory device 1100 to perform a read operation or a write operation of data DATA. As an example, the I/O request may include a read request for reading data DATA from activated memory banks. The I/O request may include a write request for writing data DATA in the activated memory banks.

Furthermore, the memory controller 1200 may generate a refresh command to control a refresh operation on the memory banks. However, the types of commands CMD described herein are merely exemplary, and other types of commands CMD may be present.

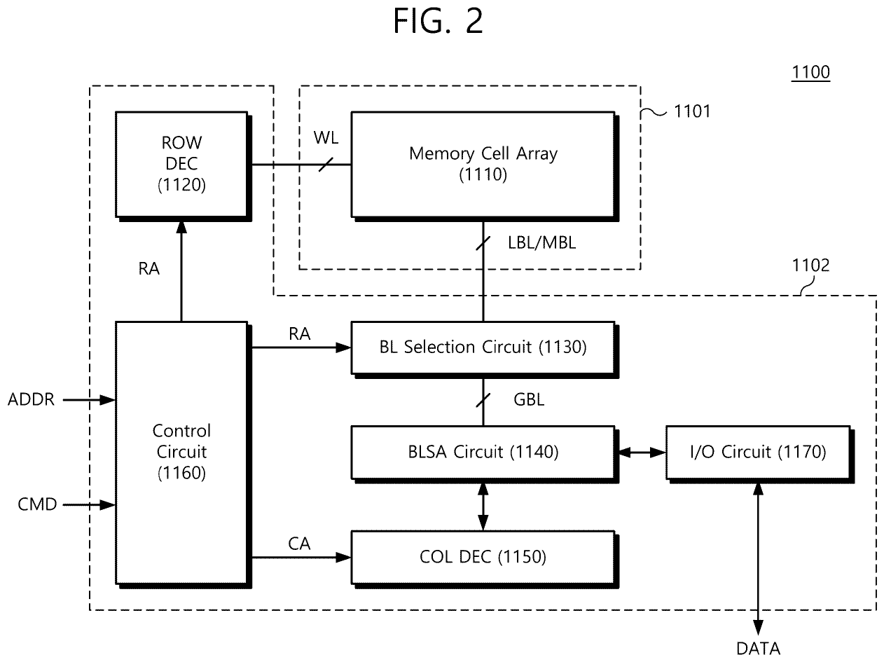

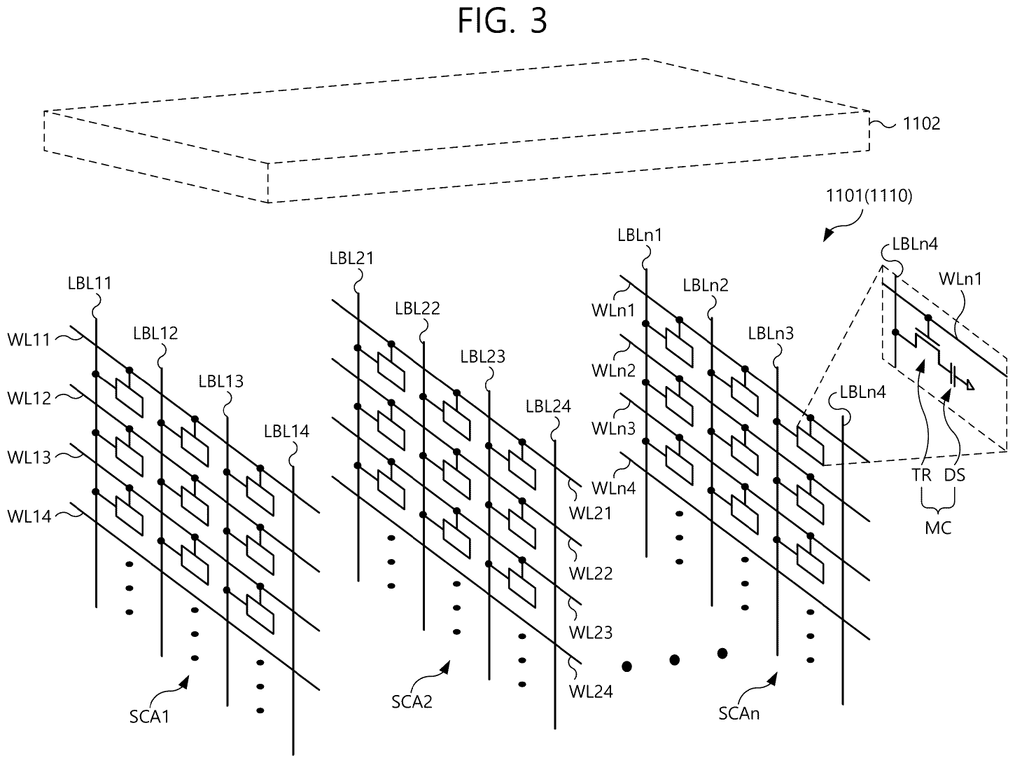

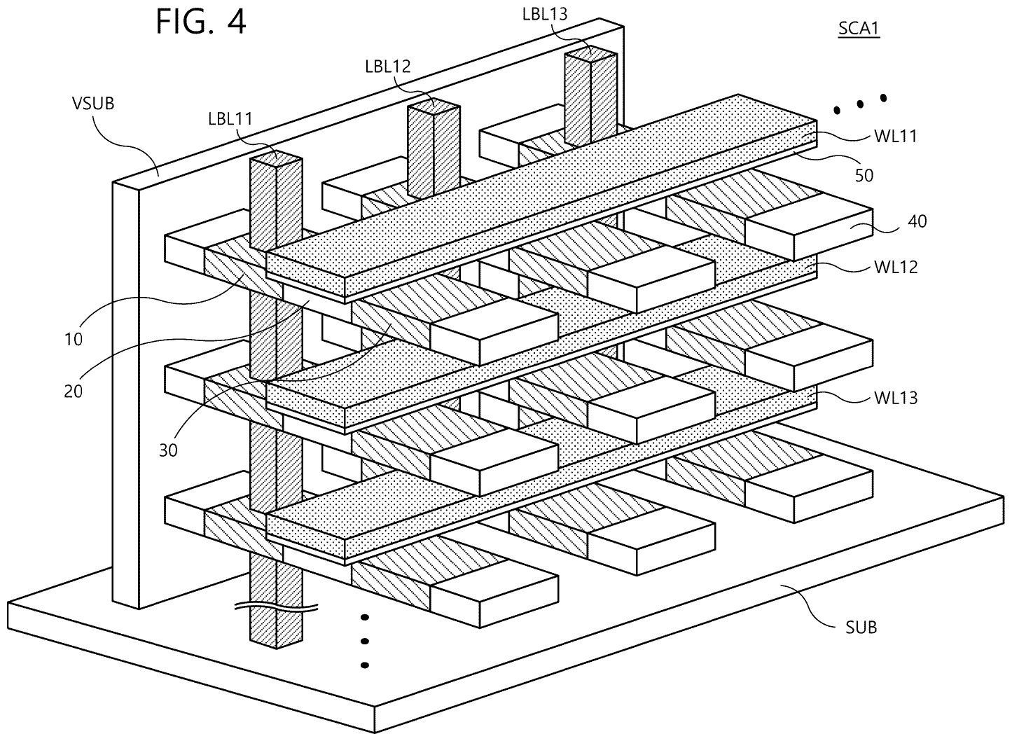

FIG. 2 is a block diagram illustrating an example of a memory device of FIG. 1. FIG. 3 is a three-dimensional diagram illustrating an example of a cell array structure of FIG. 2. FIG. 4 is a structural diagram illustrating an example of a first sub-cell array of FIG. 3. Referring to FIGS. 2 to 4, a memory device 1100 may include a cell array structure 1101 and a peripheral circuit structure 1102. For example, the cell array structure 1101 may include a memory cell array 1110 in which memory cells are stacked in three dimensions. The memory cell array 1110 may include a plurality of sub-cell arrays SCA1 to SCAn. The peripheral circuit structure 1102 may include a row decoder 1120, a bitline selection circuit 1130, a bitline sense amplifier circuit 1140, a column decoder 1150, a control circuit 1160 and/or an input/output circuit 1170.

The memory cell array 1110 may include a plurality of memory cells provided in a matrix form arranged in rows and columns. For example, the memory cell array 1110 may include a plurality of wordlines WL and a plurality of bitlines BL connected to the memory cells. The plurality of wordlines WL may be connected to the rows of the memory cells, and the plurality of bitlines BL may be connected to the columns of the memory cells.

The memory cell array 1110 may include the plurality of sub-cell arrays SCA1 to SCAn. For example, one sub-cell array (for example, the first sub-cell array SCA1) may include memory cells MC which are stacked in a vertical direction with respect to a peripheral circuit structure 1102. One sub-cell array may include a plurality of local bitlines (for example, LBL11 to LBL14) which are formed in a vertical direction with respect to the peripheral circuit structure 1102. In addition, one sub-cell array may include a plurality of wordlines (for example, WL11 to WL14) which are arranged in parallel with the peripheral circuit structure 1102.

One memory cell MC may include a selection element TR and a data storage element DS. The selection element TR and the data storage element DS may be electrically connected in series. The selection element TR may be connected between the data storage element DS and one wordline. The data storage element DS may be connected to one bitline through the selection element TR.

The cell array structure 1101 and the peripheral circuit structure 1102 may be formed on different silicon wafers and then bonded through a bonding process. For example, in the first wafer, local bitlines LBLs may be connected to one intermediate bitline in specified units (for example, two lines). The intermediate bitlines MBLs may be respectively connected to bonding pads of the first wafer. In the second wafer, the bitline selection circuit 1130 may be connected to bonding pads of the second wafer. The bonding pads of the first wafer and the bonding pads of the second wafer may be electrically connected to each other through a bonding process. Accordingly, the intermediate bitlines MBLs (or local bitlines LBLs) may be connected to the bitline selection circuit 1130 through the bonding pads.

In the first wafer, the wordlines WLs may be respectively connected to the bonding pads of the first wafer. In the second wafer, the row decoder 1120 may be connected to the bonding pads of the second wafer. The wordlines WL may be connected to the row decoder 1120 through the bonding pads. As an example, wordlines (for example, WL11, WL21 to WLn1) arranged at the same height from the peripheral circuit structure 1102 may be connected to the row decoder 1120 through the same bonding pad.

The row decoder 1120 may select one of the plurality of wordlines WL connected to the memory cell array 1110. The row decoder 1120 may decode the row address RA received from the control circuit 1160, select one wordline corresponding to the row address RA, and activate the selected wordline.

The bitline selection circuit 1130 may be connected to the intermediate bitlines MBLs of the memory cell array 1110. In addition, the bitline selection circuit 1130 may be connected to global bitlines GBLs. The bitline selection circuit 1130 may receive a row address RA from the control circuit 1160. The bitline selection circuit 1130 may connect the selected intermediate bitline MBL to each of the global bitlines GBLs based on the row address RA.

The bitline sense amplifier circuit 1140 may be connected to the global bitlines GBLs. For example, the bitline sense amplifier circuit 1140 may include a plurality of bitline sense amplifiers. The plurality of bitline sense amplifiers may be connected to the global bitlines GBLs, respectively. The bitline sense amplifier circuit 1140 may detect a voltage change of a selected bitline among a plurality of global bitlines GBLs, and amplify and output the detected voltage change.

The column decoder 1150 may select a bitline sense amplifier among the plurality of bitline sense amplifiers of the bitline sense amplifier circuit 1140. The column decoder 1150 may decode a column address CA received from the control circuit 1160 and select a bitline sense amplifier corresponding to the column address CA.

The control circuit 1160 may control an overall operation of the memory device 1100. For example, the control circuit 1160 may receive an address ADDR from the memory controller 1200 and output the row address RA and the column address CA.

The control circuit 1160 may decode a write enable signal (for example, /WE), a row address strobe signal (for example, /RAS), a column address strobe signal (for example, /CAS) and a chip select signal (for example, /CS) received from the memory controller 1200 and generate control signals corresponding to a command CMD. As an example, the command CMD may include an active request, a read request, a write request or a precharge request.

The input/output circuit 1170 may output data DATA to the memory controller 1200 through a data pad based on a sensed and amplified voltage from the bitline sense amplifier circuit 1140. For example, the input/output circuit 1170 may include an input buffer or an output buffer. The input/output circuit 1170 may perform a serialization operation or a deserialization operation of data DATA.

Referring to FIGS. 3 and 4, the memory cell array 1110 may include a plurality of sub-cell arrays SCA1 to SCAn. One sub-cell array may include memory cells vertically stacked on a substrate SUB of the cell array structure 1101.

For example, a vertical substrate VSUB may be formed on the substrate SUB. A selection element TR and a data storage element DS may be formed from the vertical substrate VSUB to be parallel to the substrate SUB. The selection element TR may include a first active region (or a first source/drain region) 10, a channel region 20 and a second active region (or a second source/drain region) 30. The first active region 10 and the second active region 30 may be separated by the channel region 20.

Each of the first active regions 10 may be connected to local bitlines LBL11, LBL12 and LBL13 extending vertically from the substrate SUB. For example, the first active regions 10 which are stacked so as to overlap from the substrate SUB may be connected to one local bitline (for example, the eleventh local bitline LBL11). As an example, each of the local bitlines LBL11, LBL12 and LBL13 may penetrate the first active regions 10 and be connected to the first active regions 10. As another example, although not illustrated, each of the local bitlines LBL11, LBL12 and LBL13 may be connected to the first active regions 10 by being closely adjacent to the side surfaces of the first active regions 10.

The wordlines WL11, WL12 and WL13 may be formed to cross the channel regions 20. Each of the wordlines WL11, WL12 and WL13 may extend in a direction perpendicular to the local bitlines LBL11, LBL12 and LBL13. The wordlines WL11, WL12 and WL13 may be formed to be horizontal to the substrate SUB. A gate insulator 50 may be arranged between each of the wordlines WL11, WL12 and WL13 and the channel regions 20.

A storage node 40 may be connected to the second active region 30. The data storage element DS may be connected to the storage node 40.

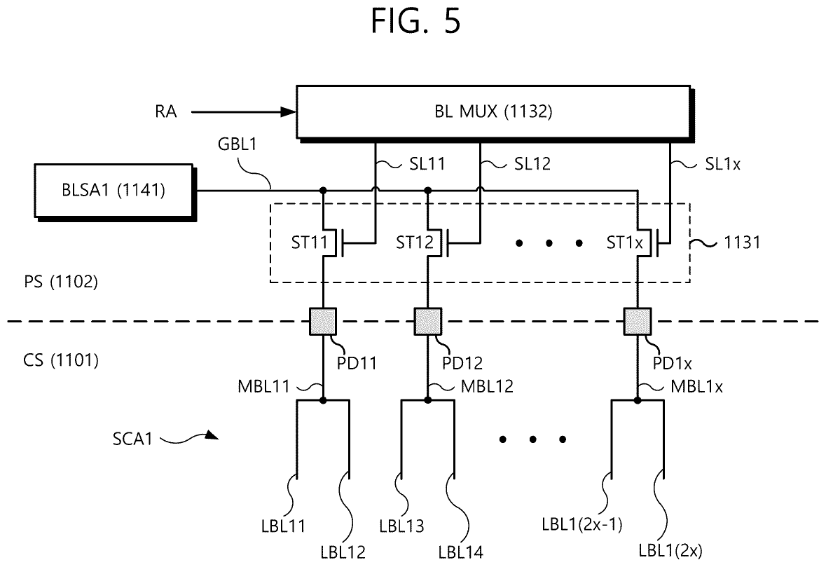

FIG. 5 is a diagram illustrating an example of a bit line selection circuit of FIG. 2. Referring to FIGS. 2 to 5, the bitline selection circuit 1130 may include selection transistors 1131 and a bitline multiplexer 1132. The bitline sense amplifier circuit 1140 may include a plurality of bitline sense amplifiers. Each of the plurality of bitline sense amplifiers may be connected to each of global bitlines. In some implementations, in FIG. 5, one bitline sense amplifier and one sub-cell array (for example, the first sub-cell array SCA1) connected to one global bitline are illustrated. However, the memory device 1100 may include a plurality of sub-cell arrays configured identically or similarly to the first sub-cell array SCA1.

One bitline sense amplifier may be connected to one global bitline. For example, a first bitline sense amplifier 1141 may be connected to a first global bitline GBL1.

One global bitline may be connected to multiple intermediate bitlines through the bitline selection circuit 1130. For example, the first global bitline GBL1 may be connected to intermediate bitlines MBL11 to MBL1x.

One intermediate bitline may be connected to local bitlines of a specified unit (for example, 2 or 3 lines, etc.). For example, the eleventh intermediate bitline MBL11 may be connected to local bitlines LBL11 and LBL12. The twelfth intermediate bitline MBL12 may be connected to local bitlines LBL13 and LBL14.

The selection transistors 1131 may selectively connect one global bitline to multiple intermediate bitlines. For example, the selection transistors 1131 may include the eleventh selection transistor ST11 to the 1x-th selection transistor ST1x. The eleventh selection transistor ST11 may connect the eleventh intermediate bitline MBL11 to the first global bitline GBL1. The twelfth selection transistor ST12 may connect the twelfth intermediate bitline MBL12 to the first global bitline GBL1. The 1x-th selection transistor ST1x may connect the 1x-th intermediate bitline MBL1x to the first global bitline GBL1.

The selection transistors 1131 may connect the intermediate bitlines MBL11 to MBL1x to the first global bitline GBL1, respectively. For example, depending on whether each of the selection transistors 1131 is turned on, each of the intermediate bitlines MBL11 to MBL1x may be selectively connected to the first global bitline GBL1.

The bitline multiplexer 1132 may select a portion of the selection transistors 1131 based on a row address RA. For example, the bitline multiplexer 1132 may transmit selection signals to selection lines SL11 to SL1x based on the row address RA. Accordingly, the row decoder 1120 may select a wordline based on the row address RA, and the bitline multiplexer 1132 may connect an intermediate bitline corresponding to the wordline selected based on the row address RA to the first global bitline GBL1. The local bitlines connected to the selected intermediate bitline may be connected to the first global bitline GBL1.

The local bitlines LBL11 to LBL1 (2x) and the intermediate bitlines MBL11 to MBL1x may be formed in the cell array structure 1101. The first global bitline GBL1, the selection transistors 1131 and the bitline multiplexer 1132 may be formed in the peripheral circuit structure 1102. The intermediate bitlines MBL11 to MBL1x may be respectively connected to the selection transistors 1131 via bonding pads. For example, the eleventh intermediate bitline MBL11 may be connected to the eleventh selection transistor ST11 via an eleventh bonding pad PD11. The twelfth intermediate bitline MBL12 may be connected to the twelfth selection transistor ST12 via a twelfth bonding pad PD12. The 1x-th intermediate bitline MBL1x may be connected to the 1x-th selection transistor ST1x via an 1x-th bonding pad PD1x.

As described above, the bitline selection circuit 1130 may connect a portion of the selected intermediate bitlines (or local bitlines) to one global bitline based on the row address RA. Accordingly, loads on one bitline sense amplifier may be reduced during a read or write operation of the memory device 1100.

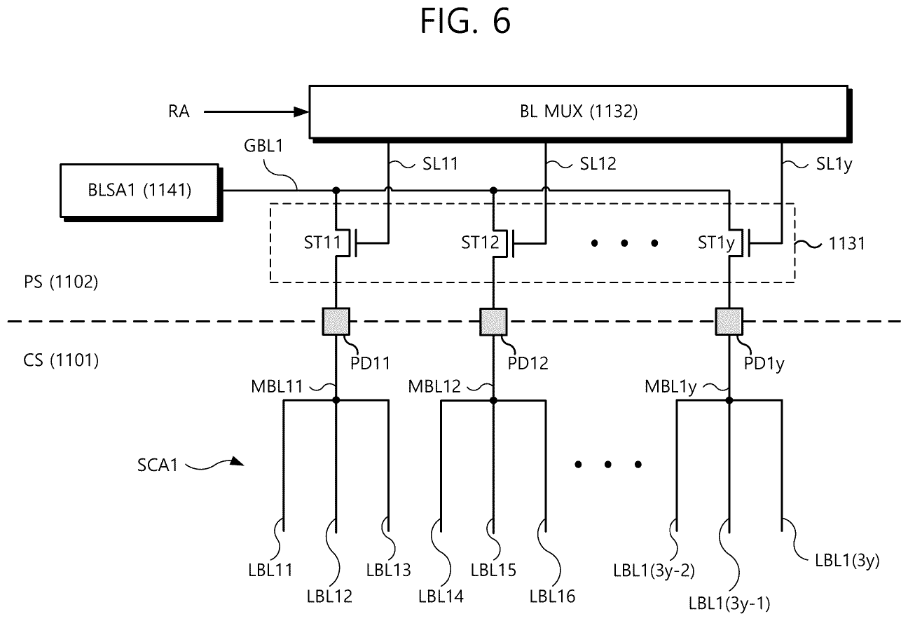

FIG. 6 is a diagram illustrating an example of a bit line selection circuit of FIG. 2. Referring to FIGS. 2, 3, and 6, the bitline selection circuit 1130 may include selection transistors 1131 and a bitline multiplexer 1132. The bitline sense amplifier circuit 1140 may include a plurality of bitline sense amplifiers. Each of the plurality of bitline sense amplifiers may be connected to each of the global bitlines. In some implementations, in FIG. 6, one bitline sense amplifier and one sub-cell array (for example, the first sub-cell array SCA1) connected to one global bitline are illustrated. However, the memory device 1100 may include a plurality of sub-cell arrays configured identically or similarly to the first sub-cell array SCA1.

One bit-line sense amplifier may be connected to one global bit-line. For example, the first bit-line sense amplifier 1141 may be connected to a first global bit-line GBL1.

One global bit-line may be connected to a plurality of intermediate bit-lines through the bit-line selection circuit 1130. For example, the first global bit-line GBL1 may be connected to intermediate bit-lines MBL11 to MBL1y.

One intermediate bit-line may be connected to local bit-lines of a specified unit (for example, 2 or 3 lines, etc.). For example, the eleventh intermediate bit-line MBL11 may be connected to local bit-lines LBL11, LBL12 and LBL13. The twelfth intermediate bitline MBL12 may be connected to local bitlines LBL14, LBL15 and LBL16.

The selection transistors 1131 may selectively connect one global bitline and a plurality of intermediate bitlines. For example, the selection transistors 1131 may include an eleventh selection transistor ST11 to a 1y-th selection transistor ST1y. The eleventh selection transistor ST11 may connect the eleventh intermediate bitline MBL11 to the first global bitline GBL1. The twelfth selection transistor ST12 may connect the twelfth intermediate bitline MBL12 to the first global bitline GBL1. The 1y-th selection transistor ST1y may connect the 1y-th intermediate bitline MBL1y to the first global bitline GBL1.

The selection transistors 1131 may connect the intermediate bitlines MBL11 to MBL1y to the first global bitline GBL1, respectively. For example, depending on whether each of the selection transistors 1131 is turned on, each of the intermediate bitlines MBL11 to MBL1y may be selectively connected to the first global bitline GBL1.

The bitline multiplexer 1132 may select a portion of the selection transistors 1131 based on a row address RA. For example, the bitline multiplexer 1132 may transmit selection signals to selection lines SL11 to SLly based on the row address RA. Accordingly, the row decoder 1120 may select a wordline based on the row address RA, and the bitline multiplexer 1132 may connect a local bitline corresponding to the wordline selected based on the row address RA to the first global bitline GBL1. The local bitlines connected to the selected local bitline may be connected to the first global bitline GBL1.

The local bitlines LBL11 to LBL1 (3y) and the intermediate bitlines MBL11 to MBL1y may be formed in the cell array structure 1101. The first global bitline GBL1, the selection transistors 1131, and the bitline multiplexer 1132 may be formed in the peripheral circuit structure 1102. The intermediate bitlines MBL11 to MBL1y may be respectively connected to the selection transistors 1131 via bonding pads. For example, the eleventh intermediate bitline MBL11 may be connected to the eleventh selection transistor ST11 via an eleventh bonding pad PD11. The twelfth intermediate bitline MBL12 may be connected to the twelfth selection transistor ST12 via a twelfth bonding pad PD12. The 1y-th intermediate bitline MBL1y may be connected to the 1y-th selection transistor ST1y via a 1y-th bonding pad PD1y.

As described above, the bitline selection circuit 1130 may connect a portion of the selected intermediate bitlines (or local bitlines) to one global bitline based on the row address RA. Accordingly, loads on one bitline sense amplifier may be reduced during a read or write operation of the memory device 1100.

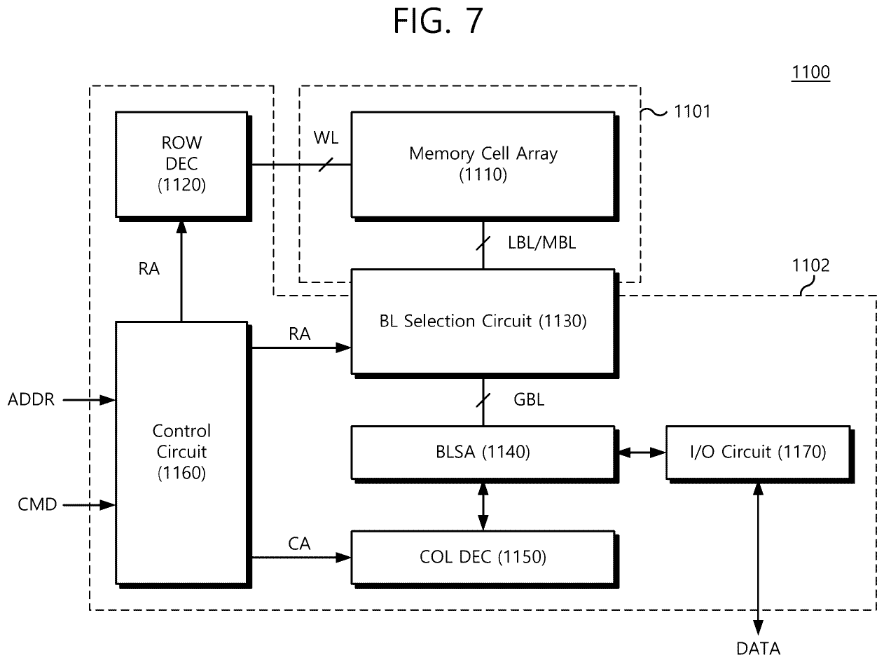

FIG. 7 is a block diagram illustrating an example of a memory device of FIG. 1. Referring to FIGS. 3 and 7, the memory device 1100 may include a cell array structure 1101 and a peripheral circuit structure 1102. For example, the cell array structure 1101 may include a memory cell array 1110 in which memory cells are stacked in three dimensions. The peripheral circuit structure 1102 may include a row decoder 1120, a bitline sense amplifier circuit 1140, a column decoder 1150, a control circuit 1160 and/or an input/output circuit 1170.

The memory cell array 1110, the row decoder 1120, the bitline sense amplifier circuit 1140, the column decoder 1150, the control circuit 1160 and/or the input/output circuit 1170 of FIG. 7 may have the same or similar configuration and features as the memory cell array 1110, the row decoder 1120, the bitline sense amplifier circuit 1140, the column decoder 1150, the control circuit 1160 and/or the input/output circuit 1170 of FIG. 2. Hereinafter, differences from the memory device 1100 of FIG. 2 will be described.

A portion of the bitline selection circuit 1130 may be formed in the peripheral circuit structure 1102. In addition, another portion of the bitline selection circuit 1130 may be formed in the cell array structure 1101.

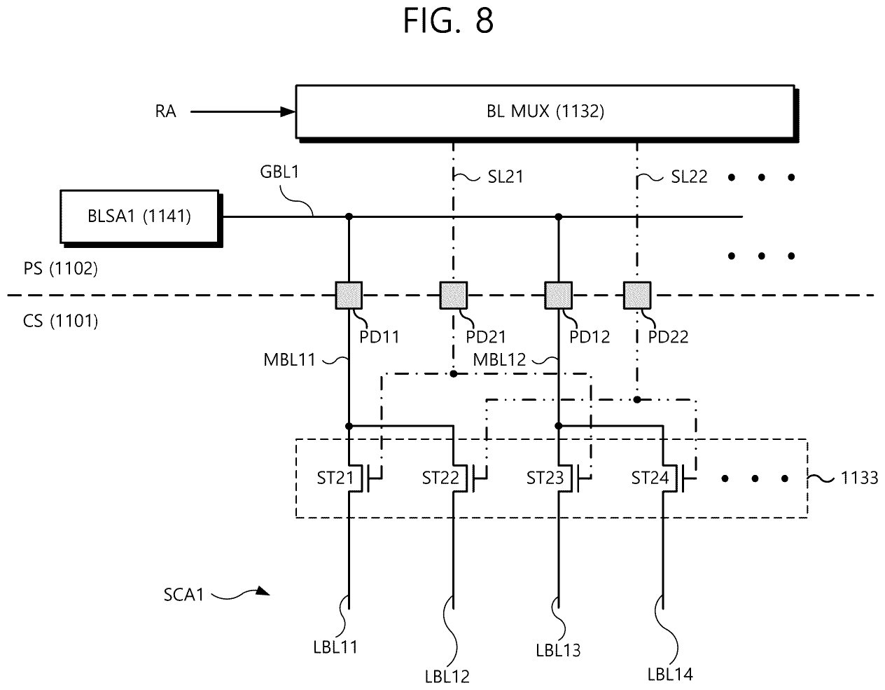

FIG. 8 is a diagram illustrating an example of a bit line selection circuit of FIG. 7. Referring to FIGS. 7 and 8, the bitline select circuit 1130 may include select transistors 1133 and a bitline multiplexer 1132. The bitline sense amplifier circuit 1140 may include a plurality of bitline sense amplifiers. Each of the plurality of bitline sense amplifiers may be connected to each of the global bitlines. In some implementations, in FIG. 8, one subcell array (for example, the first subcell array SCA1) connected to one bitline sense amplifier and one global bitline are illustrated. However, the memory device 1100 may include a plurality of sub-cell arrays configured identically or similarly to the first subcell array SCA1.

One bitline sense amplifier may be connected to one global bitline. For example, a first bitline sense amplifier 1141 may be connected to a first global bitline GBL1.

One global bitline may be connected to a plurality of intermediate bitlines through the bitline select circuit 1130. For example, the first global bitline GBL1 may be connected to intermediate bitlines MBL11 and MBL12.

One intermediate bitline may be connected to local bitlines of a specified unit (for example, 2 or 3 lines, etc.). For example, the eleventh intermediate bitline MBL11 may be connected to local bitlines LBL11 and LBL12. The twelfth intermediate bitline MBL12 may be connected to local bitlines LBL13 and LBL14.

The selection transistors 1133 may selectively connect one intermediate bitline and a plurality of local bitlines. For example, the selection transistors 1133 may include a twenty-first selection transistor ST21 to a twenty-fourth selection transistor ST24. The twenty-first selection transistor ST21 may connect the eleventh local bitline LBL11 to the eleventh intermediate bitline MBL11. The twenty-second selection transistor ST22 may connect the twelfth local bitline LBL12 to the eleventh intermediate bitline MBL11.

The twenty-third selection transistor ST23 may connect the thirteenth local bitline LBL13 to the twelfth intermediate bitline MBL12. The twenty-fourth selection transistor ST24 may connect the fourteenth local bitline LBL14 to the twelfth intermediate bitline MBL12.

The selection transistors 1133 may each connect the local bitlines LBL11 to LBL14 to the first global bitline GBL1. For example, depending on whether each of the selection transistors 1133 is turned on, each of the local bitlines LBL11 to LBL14 may be selectively connected to each of the intermediate bitlines MBL11 and MBL12, and the intermediate bitlines MBL11 and MBL12 may be connected to the first global bitline GBL1 via first bonding pads PD11 and PD12.

A portion of the local bitlines connected to one intermediate bitline may be selectively connected to the first global bitline GBL1. For example, when a turn-on signal is transmitted to a twenty-first selection line SL21, the eleventh local bitline LBL11 and the thirteenth local bitline LBL13 may be connected to the first global bitline GBL1. When a turn-on signal is transmitted to the twenty-second selection line SL22, the twelfth local bitline LBL12 and the fourteenth local bitline LBL14 may be connected to the first global bitline GBL1.

The bitline multiplexer 1132 may select a portion of the selection transistors 1133 based on a row address RA. For example, the bitline multiplexer 1132 may transmit selection signals to the selection lines SL21 and SL22 based on the row address RA. Accordingly, the row decoder 1120 may select a wordline based on the row address RA, and the bitline multiplexer 1132 may connect a local bitline corresponding to the wordline selected based on the row address RA to the first global bitline GBL1. The selected local bitlines may be connected to the first global bitline GBL1.

The selection transistors 1133, the local bitlines LBL11 to LBL14, and the intermediate bitlines MBL11 and MBL12 may be formed in the cell array structure 1101. The first global bitline GBL1 and the bitline multiplexer 1132 may be formed in the peripheral circuit structure 1102. The intermediate bitlines MBL11 and MBL12 may be connected to the first global bitline GBL1 via the first bonding pads PD11 and PD12.

In addition, gates of the selection transistors 1133 may be connected to the selection lines SL21 and SL22 via second bonding pads PD21 and PD22. Adjacent selection transistors among the selection transistors 1133 may be connected to different selection lines. Alternatively, non-adjacent selection transistors may be connected to one selection line.

As an example, non-adjacent selection transistors ST21 and ST23 may be connected to the twenty-first selection line SL21 via the twenty-first bonding pad PD21. Non-adjacent selection transistors ST22 and ST24 may be connected to the twenty-second selection line SL22 via the twenty-second bonding pad PD22.

As described above, the bitline selection circuit 1130 may connect a portion of the selected intermediate bitlines (or local bitlines) to one global bitline based on the row address RA. Accordingly, loads on one bitline sense amplifier may be reduced during a read or write operation of the memory device 1100.

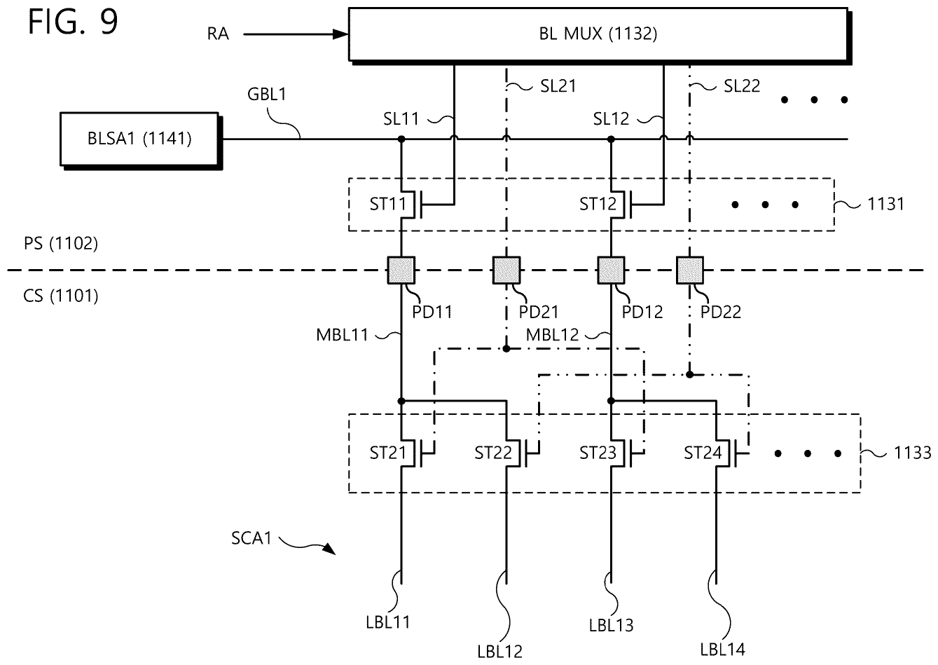

FIG. 9 is a diagram illustrating an example of a bit line selection circuit of FIG. 7. Referring to FIGS. 7 and 9, the bitline selection circuit 1130 may include first selection transistors 1131, a bitline multiplexer 1132 and/or second selection transistors 1133. The bitline sense amplifier circuit 1140 may include a plurality of bitline sense amplifiers. Each of the plurality of bitline sense amplifiers may be connected to each of the global bitlines. In some implementations, in FIG. 9, one bitline sense amplifier and one sub-cell array (for example, the first sub-cell array SCA1) connected to one global bitline are illustrated. However, the memory device 1100 may include a plurality of sub-cell arrays configured identically or similarly to the first sub-cell array SCA1.

One bitline sense amplifier may be connected to one global bitline. For example, the first bitline sense amplifier 1141 may be connected to a first global bitline GBL1.

One global bitline may be connected to multiple intermediate bitlines through the bitline selection circuit 1130. For example, the first global bitline GBL1 may be connected to intermediate bitlines MBL11 and MBL12.

One intermediate bitline may be connected to local bitlines of a specified unit (for example, 2 or 3 lines, etc.). For example, the eleventh intermediate bitline MBL11 may be connected to local bitlines LBL11 and LBL12. The twelfth intermediate bitline MBL12 may be connected to local bitlines LBL13 and LBL14.

The first selection transistors 1131 may each connect the intermediate bitlines MBL11 and MBL12 to the first global bitline GBL1. For example, depending on whether each of the first selection transistors 1131 is turned on, each of the intermediate bitlines MBL11 and MBL12 may be selectively connected to the first global bitline GBL1.

The second selection transistors 1133 may connect one intermediate bitline and each of a plurality of local bitlines. For example, depending on whether each of the second selection transistors 1133 is turned on, each of the local bitlines LBL11 to LBL14 may be selectively connected to each of the intermediate bitlines MBL11 and MBL12.

A portion of the intermediate bitlines MBL11 and MBL12 may be selectively connected to the first global bitline GBL1. For example, when a turn-on signal is transmitted to an eleventh selection line SL11, the eleventh intermediate bitline MBL11 may be connected to the first global bitline GBL1. When a turn-on signal is transmitted to the twelfth selection line SL12, the twelfth intermediate bitline MBL12 may be connected to the first global bitline GBL1.

A portion of the local bitlines connected to one intermediate bitline may be selectively connected to the first global bitline GBL1. For example, when a turn-on signal is transmitted to the twenty-first selection line SL21, the eleventh local bitline LBL11 and the thirteenth local bitline LBL13 may be connected to the first global bitline GBL1. When a turn-on signal is transmitted to the twenty-second selection line SL22, the twelfth local bitline LBL12 and the fourteenth local bitline LBL14 may be connected to the first global bitline GBL1.

The bitline multiplexer 1132 may select a portion of the first selection transistors 1131 and the second selection transistors 1133 based on a row address RA. For example, the bitline multiplexer 1132 may transmit selection signals to the selection lines SL11, SL12, SL21 and SL22 based on the row address RA. Accordingly, the row decoder 1120 may select a wordline based on the row address RA, and the bitline multiplexer 1132 may connect an intermediate bitline (or local bitline) corresponding to the wordline selected based on the row address RA to the first global bitline GBL1.

The second selection transistors 1133, the local bitlines LBL11 to LBL14, and the intermediate bitlines MBL11 and MBL12 may be formed in the cell array structure 1101. The first global bitline GBL1, the first selection transistors 1131, and the bitline multiplexer 1132 may be formed in the peripheral circuit structure 1102. The intermediate bitlines MBL11 and MBL12 may be connected to the first selection transistors 1131 via first bonding pads PD11 and PD12.

In addition, gates of the second selection transistors 1133 may be connected to the selection lines SL21 and SL22 via second bonding pads PD21 and PD22. Adjacent selection transistors among the second selection transistors 1133 may be connected to different selection lines. Alternatively, non-adjacent selection transistors may be connected to one selection line. As an example, non-adjacent selection transistors ST21 and ST23 may be connected to the twenty-first selection line SL21 via the twenty-first bonding pad PD21. Non-adjacent selection transistors ST22 and ST24 may be connected to the twenty-second selection line SL22 via the twenty-second bonding pad PD22.

As described above, the bitline selection circuit 1130 may connect some of the selected intermediate bitlines (or local bitlines) to one global bitline based on the row address RA. Accordingly, loads on one bitline sense amplifier may be reduced during a read or write operation of the memory device 1100.

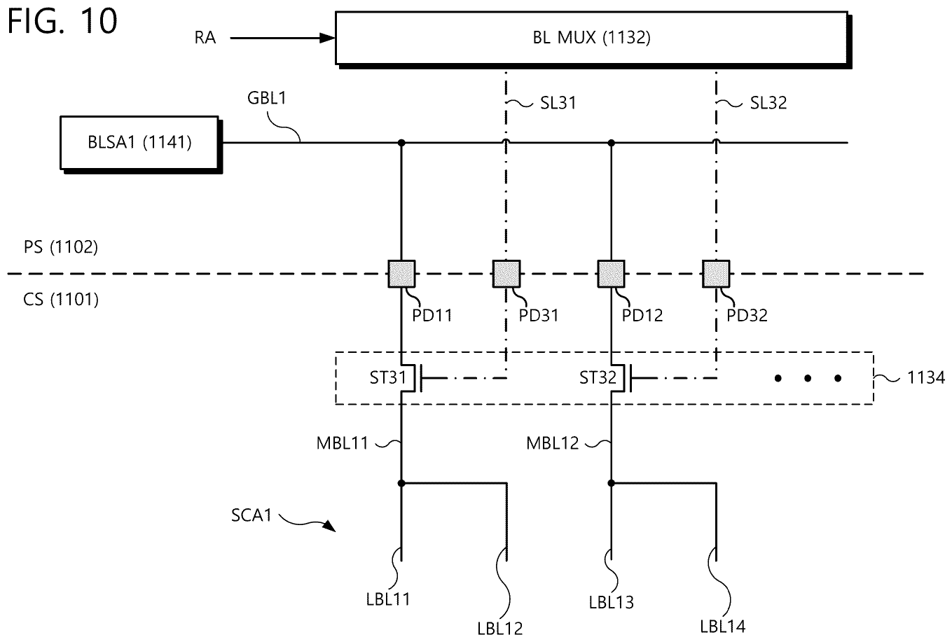

FIG. 10 is a diagram illustrating an example of a bit line selection circuit of FIG. 7. Referring to FIGS. 6 and 10, the bitline selection circuit 1130 may include selection transistors 1133 and a bitline multiplexer 1132. The bitline sense amplifier circuit 1140 may include a plurality of bitline sense amplifiers. Each of the plurality of bitline sense amplifiers may be connected to each of the global bitlines. In some implementations, in FIG. 10, one bitline sense amplifier and one sub-cell array (for example, the first sub-cell array SCA1) connected to one global bitline are illustrated. However, the memory device 1100 may include a plurality of sub-cell arrays configured identically or similarly to the first sub-cell array SCA1.

One bitline sense amplifier may be connected to one global bitline. For example, the first bitline sense amplifier 1141 may be connected to a first global bitline GBL1.

One global bitline may be connected to multiple intermediate bitlines through the bitline selection circuit 1130. For example, the first global bitline GBL1 may be connected to intermediate bitlines MBL11 and MBL12.

One intermediate bitline may be connected to local bitlines of a specified unit (for example, 2 or 3 lines, etc.). For example, the eleventh intermediate bitline MBL11 may be connected to local bitlines LBL11 and LBL12. The twelfth intermediate bitline MBL12 may be connected to local bitlines LBL13 and LBL14.

The selection transistors 1134 may selectively connect the intermediate bitlines MBL11 and MBL12 to the first global bitline GBL1. For example, the selection transistors 1134 may include a thirty-first selection transistor ST31 and a thirty-second selection transistor ST32. The thirty-first selection transistor ST31 may connect the eleventh intermediate bitline MBL11 to the first global bitline GBL1 via an eleventh bonding pad PD11. The thirty-second selection transistor ST32 may connect the twelfth intermediate bitline MBL12 to the first global bitline GBL1 via a twelfth bonding pad PD12.

The bitline multiplexer 1132 may select some of the selection transistors 1134 based on the row address RA. For example, the bitline multiplexer 1132 may transmit selection signals to selection lines SL31 and SL32 based on a row address RA. Accordingly, the row decoder 1120 may select a wordline based on the row address RA, and the bitline multiplexer 1132 may connect an intermediate bitline corresponding to the wordline selected based on the row address RA to the first global bitline GBL1. The selected local bitlines may be connected to the first global bitline GBL1.

The selection transistors 1134, the local bitlines LBL11 to LBL14, and the intermediate bitlines MBL11 and MBL12 may be formed in the cell array structure 1101. The first global bitline GBL1 and the bitline multiplexer 1132 may be formed in the peripheral circuit structure 1102. The intermediate bitlines MBL11 and MBL12 may be connected to the first global bitline GBL1 via first bonding pads PD11 and PD12. In addition, gates of the selection transistors 1134 may be connected to the selection lines SL31 and SL32 via third bonding pads PD31 and PD32.

As described above, the bitline selection circuit 1130 may connect a portion of the selected intermediate bitlines (or local bitlines) to one global bitline based on the row address RA. Accordingly, loads on one bitline sense amplifier may be reduced during a read or write operation of the memory device 1100.

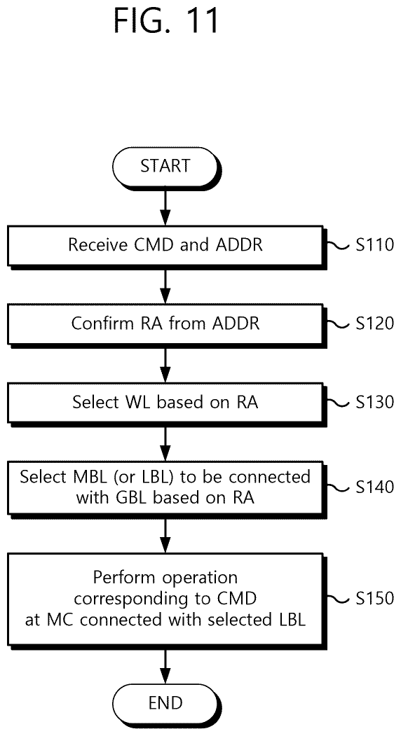

FIG. 11 is a flowchart illustrating an example of a bit line selection operation of a memory device of FIG. 2 or FIG. 7. Referring to FIGS. 2 to 11, the memory device 1100 may selectively connect a portion of local bitlines to each of global bitlines during a read or write operation to reduce loads of the bitline sense amplifier circuit 1140.

In operation S110, the memory device 1100 may receive a command CMD and an address ADDR from the memory controller 1200. For example, the control circuit 1160 may perform an operation (for example, read or write) corresponding to the command CMD for memory cells corresponding to the address ADDR.

In operation S120, the memory device 1100 may confirm a row address RA and a column address CA from the received address ADDR. For example, the control circuit 1160 may transmit the row address RA to the row decoder 1120 and the bitline selection circuit 1130. The control circuit 1160 may transmit the column address CA to the column decoder 1150.

In operation S130, the memory device 1100 may select a wordline WL based on the row address RA. For example, the row decoder 1120 may decode the row address RA to activate the selected wordline.

In operation S140, the memory device 1100 may select an intermediate bitline MBL or a local bitline LBL to be connected to a global bitline GBL based on the row address RA. For example, the bitline selection circuit 1130 may select local bitlines connected to one global bitline according to the method of FIGS. 5 to 10 based on the row address RA. The selected local bitlines may be connected to memory cells corresponding to a read or write operation of the selected wordline.

In operation S150, the memory device 1100 may perform an operation (for example, read or write) corresponding to the command CMD received from a memory cell MC connected to the selected local bitline LBL. Accordingly, loads applied to one bitline sense amplifier during the read or write operation may be reduced.

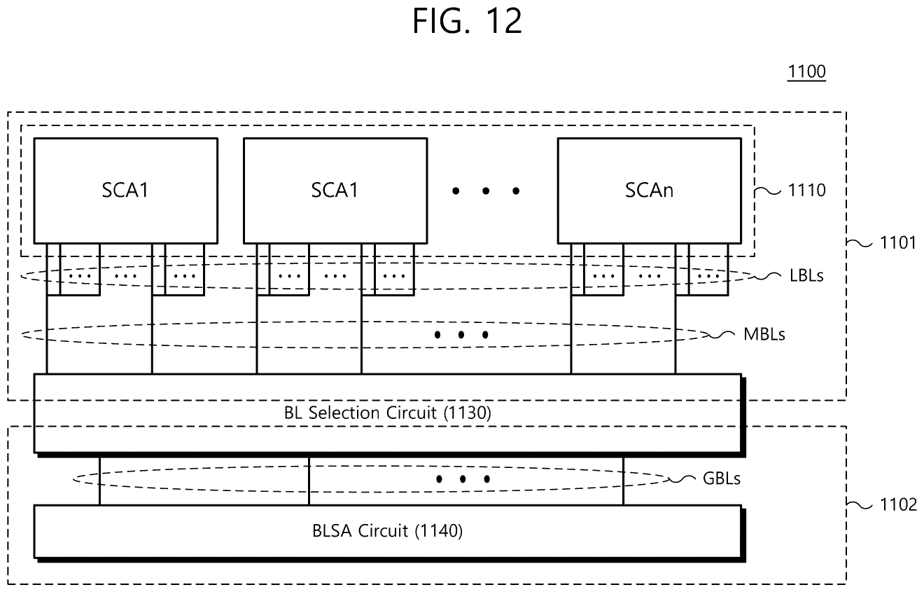

FIG. 12 is a diagram illustrating an example of a memory device of FIG. 1. Referring to FIGS. 1 and 12, a cell array structure 1101 may be stacked on a peripheral circuit structure 1102. The cell array structure 1101 may include memory cells which are vertically stacked as described in FIGS. 3 to 10. Local bitlines LBLs may be formed in a direction perpendicular to the peripheral circuit structure 1102. The local bitlines LBLs may be connected to each of intermediate bitlines MBLs in a specified unit.

The bitline selection circuit 1130 may be formed in the peripheral circuit structure 1102 or may be formed across the cell array structure 1101 and the peripheral circuit structure 1102. The bitline selection circuit 1130 may selectively connect a portion of the intermediate bitlines MBLs or the local bitlines LBLs to each of global bitlines GBLs based on a row address.

The bitline sense amplifier circuit 1140 may include a plurality of bitline sense amplifiers. The global bitlines GBLs may be connected to each of the plurality of bitline sense amplifiers.

According to the present disclosure, it may be possible to reduce loads of a bitline sense amplifier during a read or write operation.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art which various changes and modifications may be made thereto without departing from the spirit and scope of the present disclosure as set forth in the following claims.

What is claimed is:

1. A memory device comprising:
a bitline sense amplifier;
a global bitline connected with the bitline sense amplifier;
a plurality of intermediate bitlines respectively connected with a plurality of bonding pads, the plurality of bonding pads electrically connecting a peripheral circuit structure with a cell array structure;
a plurality of local bitlines connected with each of the plurality of intermediate bitlines;
a plurality of memory cells connected with each of the plurality of local bitlines; and
a bitline selection circuit configured to selectively connect a portion of the plurality of intermediate bitlines with the global bitline based on an address received from a memory controller during a read or write operation.

2. The memory device of claim 1, wherein the bitline sense amplifier, the bitline selection circuit, and the global bitline are included in the peripheral circuit structure,
wherein the plurality of intermediate bitlines, the plurality of local bitlines, and the plurality of memory cells are included in the cell array structure, and
wherein the peripheral circuit structure is configured to be bonded to the cell array structure through a bonding process.

3. The memory device of claim 1, wherein the plurality of intermediate bitlines are configured to be connected with the bitline selection circuit via the plurality of bonding pads.

4. The memory device of claim 1, wherein the bitline selection circuit comprises:
a plurality of selection transistors configured to selectively connect each of the plurality of intermediate bitlines with the global bitline according to a selection line signal; and
a bitline multiplexer configured to output the selection line signal based on a row address included in the address.

5. The memory device of claim 4, wherein the plurality of selection transistors include a first selection transistor and a second selection transistor,
wherein the first selection transistor is configured to connect a first intermediate bitline with the global bitline based on a first selection line signal, and
wherein the second selection transistor is configured to connect a second intermediate bitline with the global bitline based on the second selection line signal.

6. A memory device comprising:
a cell array structure; and
a peripheral circuit structure bonded to the cell array structure through a bonding process,
wherein the cell array structure comprises:
a memory cell array including a plurality of sub-cell arrays positioned in a direction perpendicular to a substrate;
a plurality of local bitlines extending from each of the plurality of sub-cell arrays toward the peripheral circuit structure;
a plurality of intermediate bitlines in which the plurality of local bitlines are configured to be grouped and connected; and
a plurality of first selection transistors respectively connected with the plurality of local bitlines, and
wherein the peripheral circuit structure comprises:
a bitline sense amplifier;
a global bitline connected with the bitline sense amplifier and the plurality of intermediate bitlines; and
a bitline multiplexer configured to selectively connect a portion of the plurality of local bitlines with the global bitline based on turning on a portion of the plurality of first selection transistors based on an address received from a memory controller during a read or write operation.

7. The memory device of claim 6, wherein the plurality of intermediate bitlines are connected with the global bitline via a plurality of first bonding pads between the peripheral circuit structure and the cell array structure.

8. The memory device of claim 7, wherein the peripheral circuit structure comprises a plurality of second selection transistors which are configured to selectively connect each of the plurality of intermediate bitlines with the global bitline according to a selection line signal output from the bitline multiplexer.

9. The memory device of claim 7, wherein the cell array structure comprises a plurality of second selection transistors which are configured to selectively connect each of the plurality of intermediate bitlines with the global bitline according to a selection line signal output from the bitline multiplexer.

10. The memory device of claim 9, wherein the bitline multiplexer is configured to output a plurality of first selection line signals which turn on a portion of the plurality of first selection transistors and a plurality of second selection line signals which turn on a portion of the plurality of second selection transistors based on a row address included in the address, and
wherein the plurality of first selection line signals are configured to be transmitted to the plurality of first selection transistors via a plurality of second bonding pads between the peripheral circuit structure and the cell array structure.

11. The memory device of claim 6, wherein a plurality of adjacent selection transistors among the plurality of first selection transistors are configured to receive a plurality of different selection line signals from the bitline multiplexer.

12. The memory device of claim 6, wherein a plurality of non-adjacent selection transistors among the plurality of first selection transistors are configured to receive the same selection line signal from the bitline multiplexer.

13. The memory device of claim 6, comprising:
a plurality of third selection transistors connected with each of the plurality of intermediate bitlines,
wherein the bitline multiplexer is configured to output a plurality of third selection line signals which turn on a portion of the plurality of third selection transistors based on a row address included in the address, and
wherein the plurality of third selection line signals are configured to be transmitted to the plurality of third selection transistors via a plurality of third bonding pads between the peripheral circuit structure and the cell array structure.

14. A memory device comprising:
a memory cell array including a plurality of sub-cell arrays positioned in a vertical direction on a substrate;
a plurality of local bitlines connected with a plurality of memory cells in each of the plurality of sub-cell arrays;
a plurality of intermediate bitlines in which the plurality of local bitlines are grouped and connected;
a plurality of global bitlines in which the plurality of intermediate bitlines are grouped and connected;
a plurality of wordlines connected with the plurality of memory cells and positioned in a direction perpendicular to the plurality of local bitlines;
a plurality of bitline sense amplifiers respectively connected with the plurality of global bitlines; and
a bitline selection circuit configured to selectively connect a portion of the plurality of intermediate bitlines with each of the plurality of global bitlines based on an address received from a memory controller during a read or write operation.

15. The memory device of claim 14, wherein the plurality of global bitlines, the plurality of bitline sense amplifiers, and the bitline selection circuit are included in a peripheral circuit structure,
wherein the memory cell array, the plurality of local bitlines, the plurality of intermediate bitlines, and the plurality of wordlines are included in a cell array structure, and
wherein the peripheral circuit structure is configured to be bonded to the cell array structure through a bonding process.

16. The memory device of claim 15, wherein the bitline selection circuit comprises:
a plurality of first selection transistors configured to selectively connect each of the plurality of intermediate bitlines with each of the plurality of global bitlines according to a selection line signal; and
a bitline multiplexer configured to output the selection line signal based on a row address included in the address.

17. The memory device of claim 16, comprising:
a row decoder configured to select a portion of the plurality of wordlines based on the row address,
wherein the bitline selection circuit is configured to select a portion of the plurality of intermediate bitlines corresponding to the selected wordlines based on the row address.

18. The memory device of claim 15, wherein the bitline selection circuit comprises:
a plurality of second selection transistors configured to selectively connect each of the plurality of local bitlines to each of the plurality of intermediate bitlines according to a selection line signal; and
a bitline multiplexer configured to output the selection line signal based on a row address included in the address.

19. The memory device of claim 18, wherein the plurality of intermediate bitlines are connected with the global bitline via a plurality of first bonding pads between the peripheral circuit structure and the cell array structure.

20. The memory device of claim 19, wherein
a plurality of gates of the plurality of second selection transistors are each connected with the selection line signal via a plurality of second bonding pads between the peripheral circuit structure and the cell array structure.
